(19) United States
(12) Patent Application Publication
(10) Pub. No.: US 2022/0100233 A1
(43) Pub. Date: Mar. 31, 2022

(54) STORAGE DEVICE CARRIERS

(71) Applicant: Hewlett-Packard Development Company, L.P., Spring, TX (US)

(72) Inventors: Peter Andrew Seiler, Fort Collins, CO (US); Christopher Ritchie Tabarez, Fort Collins, CO (US); Markku llmari Suomi, San Diego, CA (US); Adolfo Adolfo Gomez, Fort Collins, CO (US)

(73) Assignee: Hewlett-Packard Development Company, L.P., Spring, TX (US)

(21) Appl. No.: 17/414,982

(22) PCT Filed: May 22, 2019
(86) PCT No.: PCT/US2019/033477

§ 371 Date: Jun. 17, 2021

(51) Int. Cl. G06F 1/16; H05K 5/02

(52) U.S. Cl. CPC G06F 1/1632; H05K 5/0247; H05K 5/0221; H05K 5/0291

(57) ABSTRACT

An example system includes a portable storage device carrier to receive a plurality of drive trays. Each of the plurality of drive trays receives a storage device. The example system further includes a dock assembly to receive the portable storage device carrier. The dock assembly includes a circuit assembly to electrically couple the storage devices to a computing device.

### BACKGROUND

Many computing devices and other electronic devices, such as mobile phones, desktop and laptop computers, tablets, digital cameras, and other similar devices execute applications and store data on storage devices. Examples of storage devices include memory devices (e.g., random access memory, read-only memory, etc.), hard disk drives (HDDs), solid-state drives (SSDs), and the like.

### BRIEF DESCRIPTION OF THE DRAWINGS

The following detailed description references the drawings, in which:

FIG. 1A depicts an assembled view of a storage device assembly having a portable storage device carrier according to examples described herein;

FIG. 1B depicts an isometric exploded top view of the storage device assembly of FIG. 1A having the portable storage device carrier according to examples described herein;

FIG. 1C depicts an isometric exploded bottom view of the storage device assembly of FIG. 1A having the portable storage device carrier according to examples described herein;

FIG. 2 depicts a mobile docking adapter having a dock assembly having a portable storage device carrier disposed therein according to examples described herein;

FIG. 3 depicts a computing device having dock assemblies each having a portable storage device carrier disposed therein according to examples described herein; and

FIG. 4 depicts a block diagram of a mobile docking adapter according to examples described herein.

### DETAILED DESCRIPTION

Storage devices are commonly used to store data for use by various computing devices and other electronic devices. In some situations, a single storage device is adequate for storing data. For example, a computing device that does not store large amounts of data may only use a single storage device. However, in other situations, a computing device may utilize multiple storage devices. For example, a computing device that stores large files (e.g., video or image files, audio files, large data sets, etc.) may utilize multiple storage devices.

Further, in examples, a computing device may use multiple storage devices to provide redundancy. For example, multiple storage devices can be configured to provide redundancy for storing data such that the data are replicated across multiple storage devices. An example of such a configuration includes a redundant array of independent (or inexpensive) disks (RAID). Several different RAID configurations are possible, including RAID 0, RAID 1, RAID 2, RAID 3, RAID 4, RAID 5, and RAID 6. Other hybrid RAID and non-standard RAID configurations also exist.

In examples, it may be desirable to disconnect multiple storage devices from one computing device and reconnect the multiple storage devices to another computing device. RAID and other similar configurations for using multiple storage devices with a computing device may rely on the storage devices being enumerated in the same enumeration process in a certain enumeration configuration. The present techniques provide a portable storage device carrier that enables moving storage devices between computing devices while maintaining the configuration/arrangement of the storage devices.

For example, the storage device carrier enables the storage devices to be moved between a desktop computing environment and a mobile docking adapter such that the storage devices are presented in a static configuration. This enables presenting the storage devices as a single storage volume for mounting by a host operating system.

The storage device carrier houses a plurality of drive trays, each of which has a storage device (or devices) disposed therein. The storage devices can be, for example, non-volatile memory express (NVMe) devices, solid state drives, hard disk drives, or another suitable storage device. The storage device carrier can be inserted into a dock assembly, which is disposed in a desktop computing environment or a mobile docking adapter couplable to a computing device. Accordingly, the storage device carrier is portable between the desktop computing environment and the mobile docking adapter. An example of the portability of the storage device carrier is as follows: the portable storage device carrier can be inserted into a dock assembly in one computing environment, removed from that dock assembly, and then inserted into another dock assembly in another computing environment. When the portable storage device carrier is removed from a dock assembly, the drive trays and associated storage devices disposed in the portable storage device carrier are also removed from the dock assembly.

An example system includes a portable storage device carrier to receive a plurality of drive trays. Each of the plurality of drive trays receives a storage device. The example system further includes a dock assembly to receive the portable storage device carrier. The dock assembly includes a circuit assembly to electrically couple the storage devices to a computing device

In some examples, the storage device assembly includes switching circuitry for electrically coupling the storage devices together and to the computing device. The storage device assembly can also include one or more blind mate connectors for electrically coupling the storage devices to the dock assembly, which is disposed in the desktop computing environment, the mobile docking adapter, or another computing device.

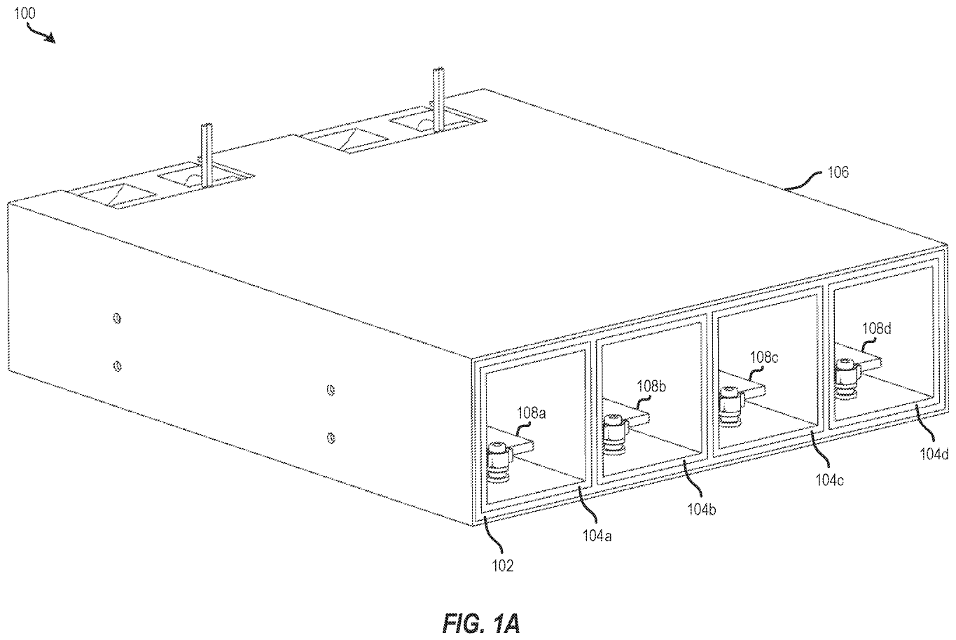

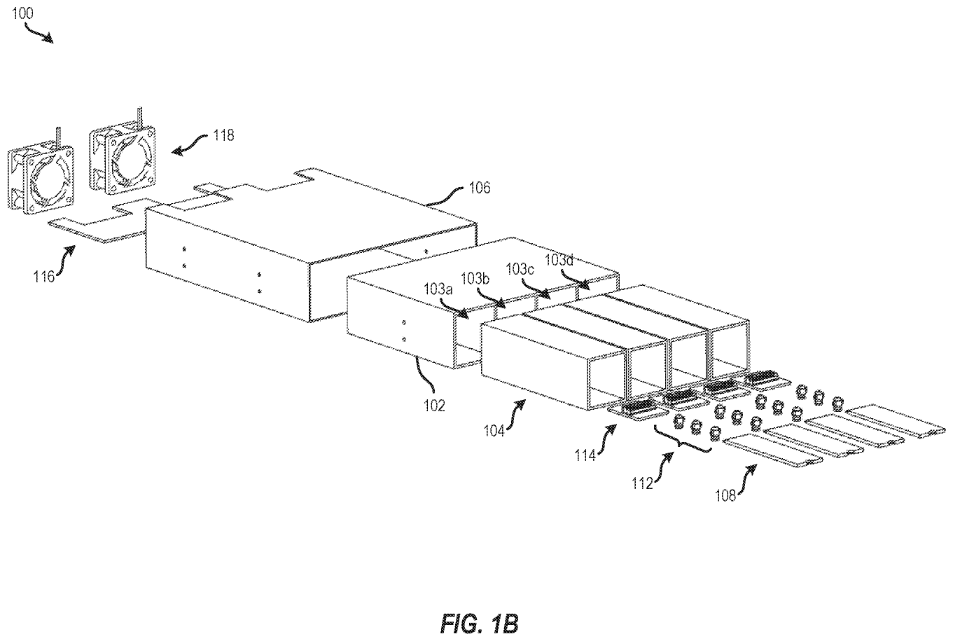

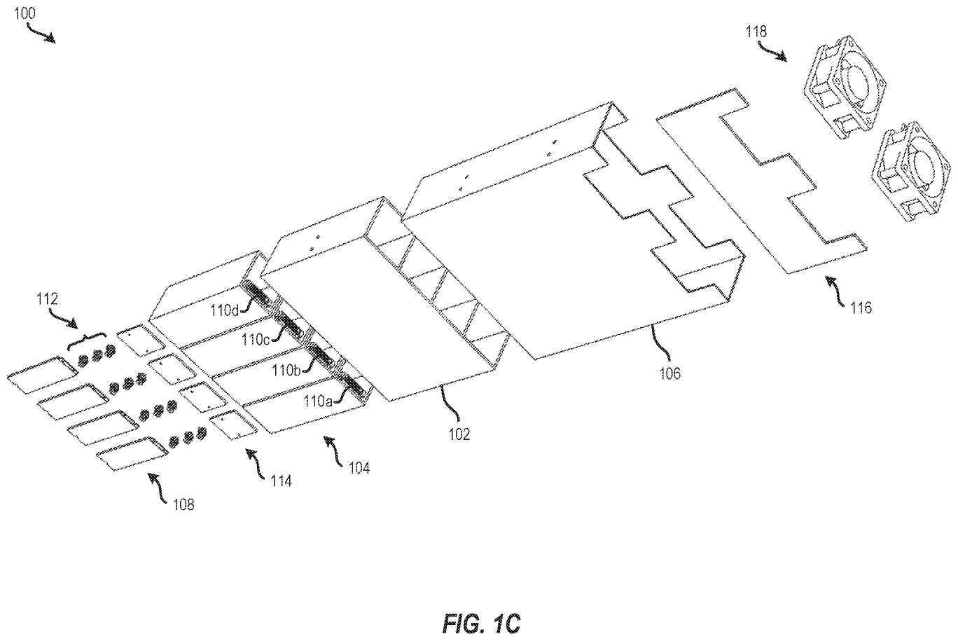

Further details of the storage device assembly and the portable storage device carrier are now described with respect to FIGS. 1-4. These figures include components according to various examples as described herein. In different examples, more, fewer, and/or other components and/or arrangements of components can be used according to the teachings described herein.

FIG. 1A depicts an assembled view of a storage device assembly 100 having a portable storage device carrier 102 according to examples described herein. FIG. 1B depicts an isometric exploded top view of the storage device assembly 100 of FIG. 1A having the portable storage device carrier 102 according to examples described herein. FIG. 1C depicts an isometric exploded bottom view of the storage device assembly 100 of FIG. 1A having the portable storage device carrier 102 according to examples described herein.

The portable storage device carrier 102 receives drive trays 104a, 104b, 104c, 104d. The drive tray receivers 103a, 103b, 103c, 103d (collectively referred to as “drive tray receivers 103”) receive the drive trays 104a, 104b, 104c, 104d respectively (collectively referred to as “drive trays 104”). Although four drive tray receivers 103 are shown, the portable storage device carrier 102 can include other numbers of drive tray receivers 103. In examples, the drive tray receivers 103 can include an alignment mechanism (e.g., rails) to align the drive tray within the drive tray receiver. In examples, the drive tray receivers 103 can include a locking mechanism to lock the drive tray within the drive tray receiver.

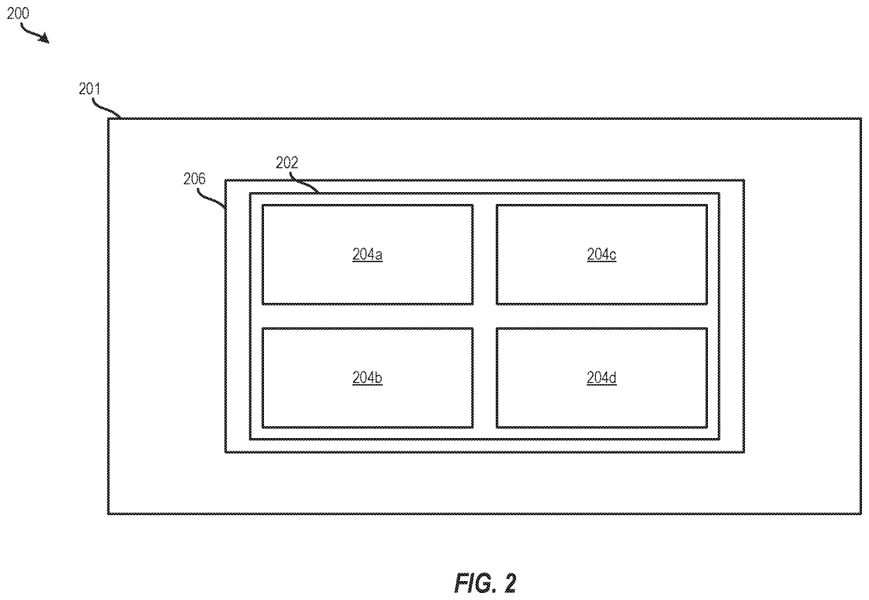

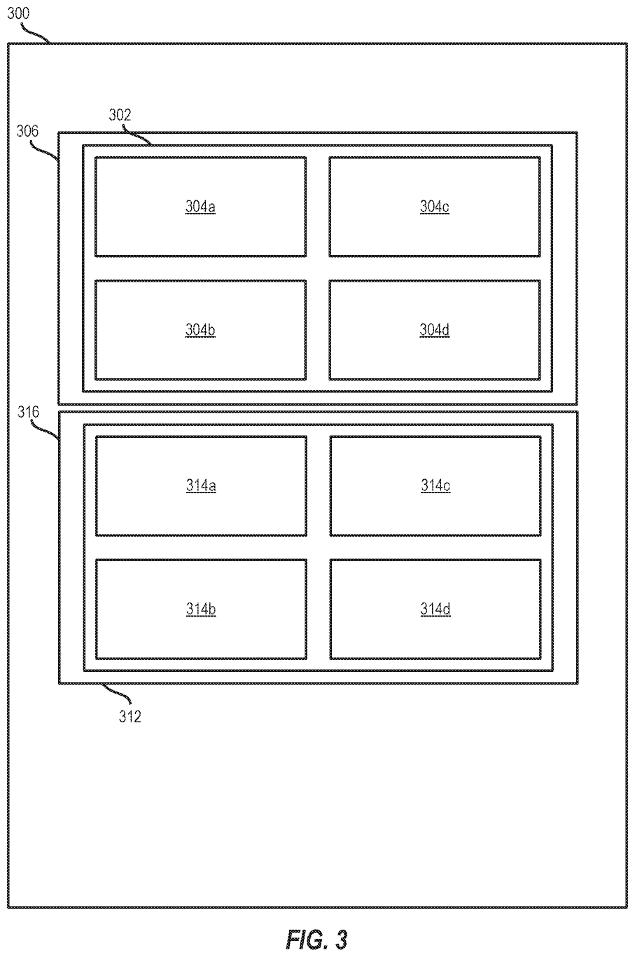

It should also be appreciated that, in other examples, the portable storage device carrier 102 can include the drive tray receivers 103 arranged in a different arrangement than shown in FIGS. 1A-1C. For example, in FIGS. 2 and 3, which include portable storage device carriers 202 and 302 respectively, the portable storage device carries 202 and 302 include four drive tray receivers arranged in a two-by-two configuration as opposed to the one-by-four configuration of FIGS. 1A-1C. In examples, other configurations of drive tray receivers 103 are possible.

The drive trays 104 include a storage device (or multiple storage devices). For example, the drive tray 104a includes a storage device 108a; similarly, the drive trays 104b, 104c, 104d include storage devices 108b, 108c, 108d respectively. The storage devices 108a-108d are collectively referred to as “storage devices 108.”

The drive trays 104 can include other components, such as fasteners 112 and a circuit board 114 (e.g., a printed circuit board). The fasteners 112 enable mounting the storage devices 108 within the drive trays 104. The storage devices 108 electrically couple to the circuit board 114. The circuit board 114 can include two separate electrical connectors: a device-side electrical connector to connect the storage devices 108 to the circuit board 114 and a dock-side electrical connector (e.g., the dock-side electrical connectors 110a, 110b, 110c, 110d) to connect the circuit board 114 to a circuit board 116 (e.g., a printed circuit board) associated with a dock assembly 106.

The dock assembly 106 receives the portable storage device carrier 102. In examples, the dock assembly 106 is configured to be disposed in a standard size drive bay of a mobile docking adapter (e.g., the mobile docking adapter 200 of FIG. 2), a computing device (e.g., the computing device 300 of FIG. 3), and/or the like. Examples of such standard size drive bays include 5.25″ drive bays, 3.5″ drive bays, 2.5″ drive bays, and the like. In examples, the dock assembly 106 can be disposed in a drive bay of another suitable size other than a standard size drive bay. In some examples, the dock assembly 106 includes fans 118 to circulate air, which can cool the storage devices 108.

FIG. 2 depicts a mobile docking adapter 200 having a dock assembly 206 for a portable storage device carrier 202 disposed therein according to examples described herein.

In this example, the mobile docking adapter 200 includes a housing 201. The housing 201 receives the portable storage device carrier 202 that contains drive trays 204a, 204b, 204c, 204d (referred to collectively as “drive trays 204”). As shown, the drive trays 204 are arranged in the portable storage device carrier 202 in a two-by-two configuration, although other configurations are possible (see, for example, the one-by-four configuration of FIG. 1). The drive trays 204 each include one or more storage devices (e.g., one or more of the storage devices 108 of FIG. 1).

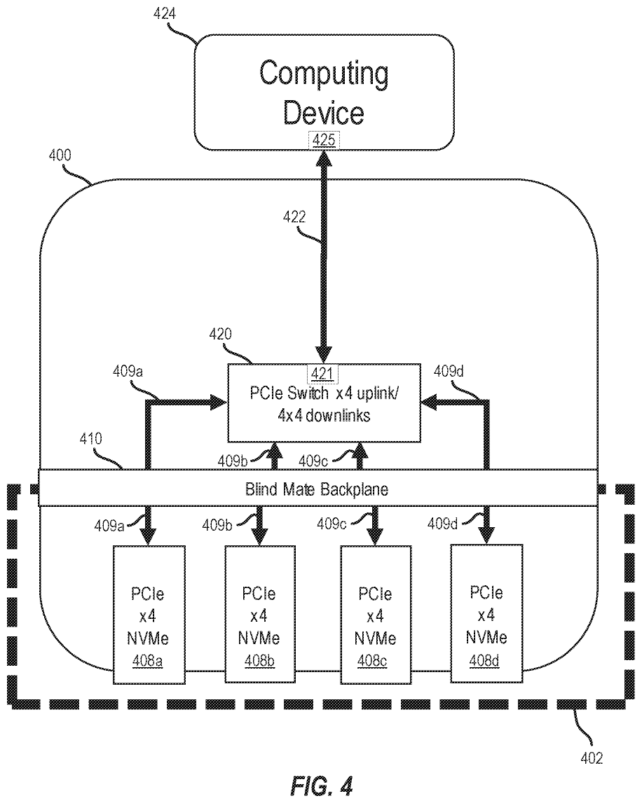

The mobile docking adapter 200 also includes a dock assembly 206. The dock assembly 206 receives the portable storage device carrier 202. Although not shown in FIG. 2, the dock assembly 206 includes a circuit assembly (e.g., the bland mate backplane 410 and the switching circuit 420 of FIG. 4) to electrically couple the storage devices (e.g., the storage devices 108 of FIG. 1) to a computing system (e.g., the computing system 424 of FIG. 4).

FIG. 3 depicts a computing device 300 having a dock assembly 306 having a portable storage device carrier 302 disposed therein according to examples described herein. In this example, the computing device 300 also includes a dock assembly 316 having a portable storage device carrier 312 disposed therein.

The dock assembly 306 receives the portable storage device carrier 302. The portable storage device carrier 302 contains drive trays 304a, 304b, 304c, 304d (referred to collectively as “drive trays 304”). As shown, the drive trays 304 are arranged in the portable storage device carrier 302 in a two-by-two configuration, although other configurations are possible (see, for example, the one-by-four configuration of FIG. 1).

Similarly, the dock assembly 316 receives the portable storage device carrier 312. The portable storage device carrier 312 contains drive trays 314a, 314b, 314c, 314d (referred to collectively as “drive trays 314”). As shown, the drive trays 314 are arranged in the portable storage device carrier 312 in a two-by-two configuration, although other configurations are possible (see, for example, the one-by-four configuration of FIG. 1).

It should be appreciated that the portable storage device carrier 302 can be removed from the dock assembly 306. When the portable storage device carrier 302 is removed from the dock assembly 306, the drive trays 304 and associated storage devices are removed as well together with the portable storage device carrier 302. The portable storage device carrier 302 can then be inserted into another dock assembly, such as the dock assembly 316 (or the dock assembly 206 of FIG. 2). When removed and reinserted, the drive trays 304 (and the associated storage devices) remain in the same configuration/arrangement, thus remaining in a static configuration. In other words, the storage device carrier enables the storage devices to be moved between docking assemblies such that the storage devices are presented in a static configuration. Similarly, the portable storage device carrier 312 can be removed from the dock assembly 316 and inserted into another dock assembly.

FIG. 4 depicts a block diagram of a mobile docking adapter 400 for a portable storage device carrier 402 according to examples described herein. In this example, the mobile docking adapter 400 is electrically coupled to a computing device 424, such as by a cable 422.

According to the example of FIG. 4, the mobile docking adapter 400 includes a portable storage device carrier 402, a blind mate backplane 410, a switching circuit 420, and a housing (e.g., the housing 201 of FIG. 2).

The portable storage device carrier 402 receives a plurality of drive trays (not shown), which include the storage devices 408. More particularly, the mobile docking adapter 400 includes a portable storage device carrier 402, represented by dashed lines. The portable storage device carrier 402 receives drive trays (not shown) (e.g., drive trays 104 of FIG. 1) that include storage devices 408a, 408b, 408c, 408d (collectively referred to as “storage devices 408”). In this example, the storage devices 408 are a peripheral component interconnect express (PCIe) NVMe devices, although other types of storage devices can be used instead of or in addition to the PCIe NVMe devices.

The mobile docking adapter 400 includes a blind mate backplane 410 to which the storage devices 408 electrically couple. The blind mate backplane 410 includes a first set of connectors and a second set of connectors that mate to the first set of connectors. The connectors are also referred to as blind mate connectors. The blind mate backplane 410 electrically couples the storage devices 408 to a switching circuit 420. In particular, the blind mate backplane establishes connections 409a, 409b, 409c, 409d between the storage devices 408 and the switching circuit 420. The portable storage device carrier 402, when inserted into the mobile docking adapter 400, causes connectors (not shown) on the storage devices 408 to electrically couple to the blind mate backplane 410.

The blind mate backplane 410 is electrically coupled to the switching circuit 420, which can be a PCIe switch with ×4 uplink and 4×4 downlinks, although other types of switches can be used instead of or in addition to the PCIe switch. The switching circuit 420 also includes a port 421 to receive the cable 422. The computing device 424 also includes a port 425 to receive the cable 422. The cable 422 can be any suitable cable for transmitting data to and receiving data from the computing device 424. For example, the cable 422 can be a universal serial bus (USB) cable, a Firewire cable, an Ethernet cable, a PCIe cable, a THUNDERBOLT cable, external serial advanced technology attachment (eSATA) cable, or any other suitable cable for transmitting/receiving data. In some examples, the cable 422 is also capable of transmitting power between the computing device 424 and the mobile docking adapter 400 to provide power to the storage devices 408.

The blind mate backplane 410 together with the switching circuit 420 are referred to as a circuit assembly. The circuit assembly can also be included in a dock assembly (e.g., the dock assembly 106 of FIG. 1), for example, to couple the storage devices 108 to a computing system.

The mobile docking adapter 400 also includes the housing (e.g., the housing 201) to receive the portable storage device carrier 402.

It should be emphasized that the above-described examples are merely possible examples of implementations and set forth for a clear understanding of the present disclosure. Many variations and modifications may be made to the above-described examples without departing substantially from the spirit and principles of the present disclosure. Further, the scope of the present disclosure is intended to cover any and all appropriate combinations and sub-combinations of all elements, features, and aspects discussed above. All such appropriate modifications and variations are intended to be included within the scope of the present disclosure, and all possible claims to individual aspects or combinations of elements are intended to be supported by the present disclosure.

What is claimed is:

1. A system comprising:
a portable storage device carrier to receive a plurality of drive trays, each of the plurality of drive trays to receive a storage device; and
a dock assembly to receive the portable storage device carrier, the dock assembly comprising a circuit assembly to electrically couple the storage devices to a computing device.

2. The system of claim 1, wherein the dock assembly is disposed in the computing device.

3. The system of claim 1, wherein the dock assembly is disposed in a mobile docking adapter external to and electrically coupled to the computing device.

4. The system of claim 1, wherein the circuit assembly comprises a plurality of connectors to electrically couple the storage device of each of the plurality of drive bays to the circuit assembly.

5. The system of claim 1, wherein the portable storage device carrier comprises drive tray receivers.

6. The system of claim 5, wherein the drive tray receivers each comprises an alignment mechanism to align the drive tray within the drive tray receiver.

7. The system of claim 5, wherein the drive tray receivers each comprises a locking mechanism to lock the drive tray within the drive tray receiver.

8. A system comprising:
a portable storage device carrier to receive a plurality of drive trays, each of the plurality of drive trays to receive a storage device; and
a dock assembly to receive the portable storage device carrier, the dock assembly comprising a circuit assembly comprising a blind mate connector to electrically couple the circuit assembly to the storage device of each of the plurality of drive trays.

9. The system of claim 8, wherein the dock assembly is disposed in a mobile docking adapter external to and electrically coupled to a computing device by a cable between the computing device and the circuit assembly.

10. The system of claim 9, wherein the portable storage device carrier, when inserted into the mobile docking adapter, causes connectors on the storage devices to electrically couple to the blind mate connector to form an electrical connection between the storage devices and the computing device.

11. A mobile docking adapter comprising:
a portable storage device carrier to receive a plurality of drive trays, the plurality of drive trays comprising storage devices;
a blind mate backplane having a first set of connectors and a second set of connectors that mate to the first set of connectors, the blind mate backplane electrically coupling the plurality of storage devices to a switching circuit; and
a housing to receive the portable storage device carrier.

12. The mobile docking adapter of claim 11, further comprising a cable to electrically couple the mobile docking adapter to the computing device, wherein a first end of the cable couples to a port of the computing device and wherein a second end of the cable couples to the switching circuit.

13. The mobile docking adapter of claim 11, wherein each of the plurality of drive trays comprises a storage device.

14. The mobile docking adapter of claim 11, wherein each of the plurality of drive trays comprises a plurality of storage devices.

15. The mobile docking adapter of claim 11, wherein the portable storage device carrier, when inserted into the mobile docking adapter, causes connectors on the storage devices to electrically couple to the blind mate backplane.
